(19) United States
(12) Patent Application Publication
(10) Pub. No.: US 2016/0276143 A1
(43) Pub. Date: Sep. 22, 2016

(54) TARGET FOR MAGNETRON SPUTTERING

(71) Applicant: TANAKA KIKINZOKU KOGYO K.K., Tokyo (JP)

(72) Inventors: Yasuyuki GOTO, Tsukuba-shi, Ibaraki (JP); Yusuke KOBAYASHI, Tsukuba-shi, Ibaraki (JP); Yasunobu WATANABE, Tsukuba-shi, Ibaraki (JP)

(21) Appl. No.: 15/032,849

(22) PCT Filed: Oct. 28, 2014
(86) PCT No.: PCT/JP2014/079153

§ 371 Date: Apr. 28, 2016

(30) Foreign Application Priority Data
Oct. 29, 2013 (JP) 2013-223905

(51) Int. Cl. H01J 37/34; C23C 14/10; C23C 14/14; B22F 9/04; C23C 14/35; C22C 19/07; B22F 3/10; B22F 1/00; C23C 14/08; C23C 14/34

(52) U.S. Cl. CPC H01J 37/3429; C23C 14/083; C23C 14/10; C23C 14/14; C23C 14/3414; C23C 14/35; C22C 19/07; B22F 3/10; B22F 1/0003; B22F 9/04; B22F 2009/045; B22F 2301/15; B22F 2302/256; B22F 2302/25

(57) ABSTRACT

The invention provides a new sputtering target that provides a large leakage of magnetic flux, is free of the risk of a change of composition during deposition, and enables deposition under a stable voltage.

A sputtering target is that having (1) a Co—Pt magnetic phase including Co and Pt, wherein Pt is included at a proportion of 4 atomic % to 10 atomic %; (2) a Co—Cr—Pt nonmagnetic phase including Co, Cr and Pt, wherein Co and Cr are included at proportions of 30 atomic % or more of Cr and 70 atomic % or less of Co; and (3) an oxide phase including finely dispersed metal oxides.

### TECHNICAL FIELD

The present invention relates to a target for magnetron sputtering for use in manufacture of a magnetic recording medium and a manufacture process of the same.

### BACKGROUND ART

Generally, when manufacturing computer hard disks and other magnetic recording media, the magnetron sputtering method is used to deposit magnetic thin films that retain magnetic records. Sputtering is a technique of ejecting atoms by bombarding a target surface with plasma occurring from ionization of gas introduced into a vacuum space and depositing those atoms to a substrate surface.

Magnetron sputtering is a method of performing sputtering by placing magnets on back of the target so that magnetic flux would leak out to the target surface, i.e., pass-through flux (PTF), thereby inducing concentration of plasma around the target. This method improves the deposition efficiency as well as prevents plasma from damaging the substrate.

A problem encountered when depositing magnetic thin films by magnetron sputtering is the low efficiency of sputtering, the problem being caused by the ferromagnetic nature of the sputtering target per se transmitting the magnetic flux from the magnet on back of the target through the target, and thus reducing a value of pass-through-flux (PTF).

Against this problem, various ideas have been implemented in an effort to increase the value of pass-through-flux (PTF). For example, JP Patent No. 4422203 describes significantly improving the pass-through-flux (PTF) by using a two-phase structured sputtering target including a magnetic phase comprising Co and Cr as main components, and a nonmagnetic phase comprising Pt as a main component.

However, because it includes a nonmagnetic phase containing Pt as the main component, the target of JP Patent No. 4422203 encounters a change of composition during deposition. In particular, the speed of sputtering differs by element and Pt has a relatively fast deposition speed compared to the other metals in the target, Co and Cr, so a nonmagnetic phase containing Pt as the main component in the target would be deposited before other parts causing more Pt to exist in the deposited thin film than in the composition of the target. When the deposition process is continued under such circumstances, Pt in the target would be consumed preferentially over time, and the Pt content in the deposited thin film would gradually decrease.

Furthermore, the method of JP Patent No. 4422203 uses a powder prepared by atomization when manufacturing the target, but a powder prepared by atomization contains voids called blow halls within. These voids lead to instable voltage when they appear on the target surface during sputtering, because plasma concentrates around these voids. There is thus a need of a means to reduce these voids.

### SUMMARY OF INVENTION

The object of the present invention is to provide a new target for magnetron sputtering providing a high pass-through-flux (PTF), free of the risk of a change of composition during deposition, and enabling deposition under a stable voltage.

The target for magnetic recording medium used in magnetron sputtering is faced with a dilemma in which it is required to include a ferromagnetic metal element so as to produce a magnetic recording medium having a magnetic recording layer with a strong coercive force, whereas the ferromagnetic metal element transmits magnetic flux from the magnet on back of the target and reduces the pass-through-flux (PTF), making sputtering inefficient. The present inventors conducted extensive research on a target for magnetron sputtering, and they consequently found that the high pass-through-flux (PTF) can be achieved, while containing a ferromagnetic metal element in a target for magnetic sputtering, by forming a magnetic phase and a non-magnetic phase, which consist of a Co-based alloy comprising a specific ratio of Pt and Cr against Co (a ferromagnetic metal), and oxide phase in the target.

The target for magnetron sputtering of the present invention is characterized in that it has a three-phase structure consisting of (1) a Co—Pt magnetic phase including Co and Pt, wherein Pt is included at a proportion of 4 to 10 atomic % against Co; (2) a Co—Cr—Pt nonmagnetic phase including Co, Cr and Pt, wherein Cr is included at a rate of 30 atomic % or more against Co; and (3) an oxide phase including finely dispersed metal oxides.

In the present specification as well as the Claims, the term “nonmagnetic” means that the effect of the magnetic field is negligibly small, and the term “magnetic” means that the effect of the magnetic field exists.

The present disclosure provides a target for magnetron sputtering having the following aspects and a manufacture method thereof.

A target for magnetron sputtering that has a three-phase structure as follows (1) a Co—Pt magnetic phase including Co and Pt, wherein Pt is included at a proportion of 4 to 10 atomic %; (2) a Co—Cr—Pt nonmagnetic phase including Co, Cr and Pt, wherein Co and Cr are included at proportions of 30 atomic % or more of Cr and 70 atomic % or less of Co; and (3) an oxide phase including finely dispersed metal oxides. The Co—Cr—Pt nonmagnetic phase could further optimally include at least one element selected from a group consisting of B, Ti, V, Mn, Zr, Nb, Ru, Mo, Ta and W. The oxide phase could comprise an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof. The Co—Pt magnetic phase can have a cross section with a circular or elliptic shape in which an aspect ratio of a major axis and a minor axis is in a range of 1 to 2.5 or a polygonal shape in which an aspect ratio of a longest distance between opposing vertexes and a shortest distance between opposing vertexes is in a range of 1 to 2.5, when observed by an electron microscope.

The Co—Cr—Pt nonmagnetic phase can have a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher, when observed by an electron microscope.

A manufacture process of a target for magnetron sputtering is also disclosed.

A first mixing step is performed for formulating a first powder mixture by mixing an oxide and a nonmagnetic metal powder comprising Co, Cr and Pt, wherein Co and Cr are included at proportions of 30 atomic % or more of Cr and 70 atomic % or less of Co.

A second mixing step is performed for formulating a second powder mixture by mixing the first powder mixture, and a magnetic metal powder comprising Co and Pt, wherein Pt is included at a proportion of 4 to 10 atomic %.

A sintering step is performed on the second powder mixture.

The nonmagnetic metal powder may include at least one element selected from a group consisting of B, Ti, V, Mn, Zr, Nb, Ru, Mo, Ta, W. The oxide powder may include an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof. The magnetic metal powder may be formulated as an alloy. And, the nonmagnetic metal powder and the magnetic metal powder are alloy powders may be formulated by an atomization method. An additional step of collapsing a blow hole by applying a mechanical treatment on the magnetic metal powder may optimally be performed before the second mixing step.

The targets for magnetron sputtering disclosed herein can be constituted to have a high pass-through-flux (PTF), almost no risk of a change of composition, and a capability of deposition at a stable voltage to be provided.

### BRIEF DESCRIPTION OF DRAWINGS

FIG. 1 is a graph illustrating the correlation between the Pt content in the Co—Pt alloy and the attaching force to a magnet.

FIG. 2 is a graph illustrating the correlation between the Cr content in the Co—Cr alloy and the attaching force to a magnet.

FIG. 3 is a metallurgical microscope photograph of the target for magnetron sputtering prepared in Example 1 of the present disclosure with description added to it.

FIG. 4 is a metallurgical microscope photograph of the target for magnetron sputtering prepared in Example 1 of the present disclosure.

FIG. 5 is a metallurgical microscope photograph of the target for magnetron sputtering prepared in Example 1 of the present disclosure.

FIG. 6 is a electron microscope photograph of the target for magnetron sputtering prepared in Example 1 of the present disclosure.

FIG. 7 is a result of an analysis of the target for magnetron sputtering prepared in Example 1 of the present disclosure with an electron probe microanalyzer (EPMA).

FIG. 8 is a metallurgical microscope photograph of the target for magnetron sputtering prepared in Comparative Example 1.

FIG. 9 is a metallurgical microscope photograph of the target for magnetron sputtering prepared in Comparative Example 1.

FIG. 10 is a metallurgical microscope photograph of the target for magnetron sputtering prepared in Comparative Example 2.

FIG. 11 is a metallurgical microscope photograph of the target for magnetron sputtering prepared in Comparative Example 2.

### DESCRIPTION OF EMBODIMENTS

Representative magnetron targets and methods for creating the same are described in detail below without being limited thereby.

The disclosed target for magnetron sputtering has a three-phase structure consisting of (1) a Co—Pt magnetic phase including Co and Pt, wherein Pt is included at a proportion of 4 to 10 atomic %; (2) a Co—Cr—Pt nonmagnetic phase including Co, Cr and Pt, wherein Co and Cr are included at proportions of 30 atomic % or more of Cr and 70 atomic % or less of Co; and (3) an oxide phase including finely dispersed metal oxides. Each of the phases are described in detail below.

1. Components of the Target

The target for magnetron sputtering comprises at least Co, Cr, Pt and an oxide. As long as a Co—Pt magnetic phase, a Co—Cr—Pt nonmagnetic phase and an oxide phase are formed, the target may further include at least one element selected from a group consisting of B, Ti, V, Mn, Zr, Nb, Ru, Mo, Ta, and W.

The content ratios of the metal and the oxide against the entire target are determined according to the composition of the components of the desired magnetic recording layer, and the content ratios against the entire target are preferably 90 to 94 mole % for metal, and 6 to 10 mole % for oxides.

Co is a ferromagnetic metal element, and it plays a main part when forming granularly structured magnetic particles for a magnetic recording layer. The content ratio of Co against the total metal is preferably 60 to 75 atomic %.

2. Co—Pt Magnetic Phase

The Co—Pt magnetic phase may further include impurities or intentional additive elements as long as it is a magnetic phase containing Co as the main component and 4 to 10 atomic % of Pt.

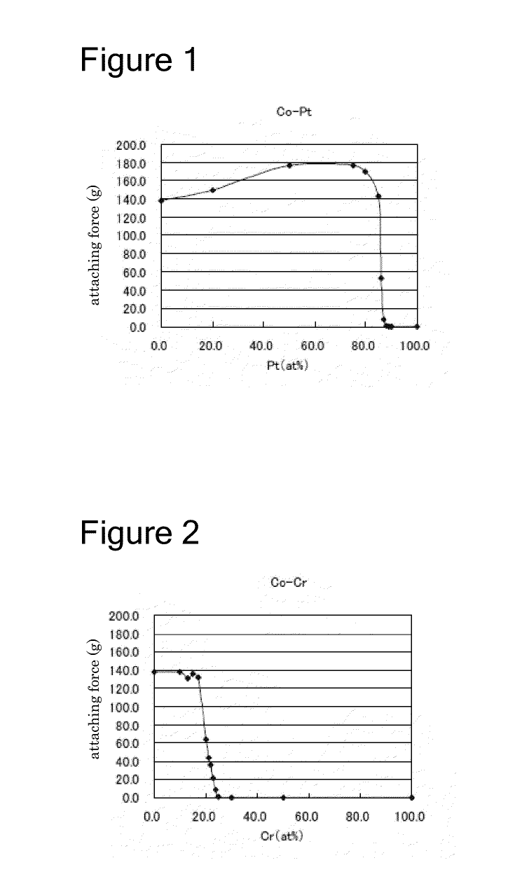

FIG. 1 illustrates the effect of the amount of Pt in an alloy comprising Co and Pt (hereinafter referred to as “Co—Pt alloy”) on an attaching force to a magnet. Co and Pt were mixed with different compositional ratios to a volume of 1 cm³, and subjected to arc melting to form a disk-like sample with a bottom area of 0.785 cm², and the bottom surface of the sample was attached to a magnet (ferrite) with a residual magnetic flux density of 500 Gauss, then it was pulled in a direction vertical to the bottom surface. The force when the sample separated from the magnet was measured. The force was divided by the bottom area 0.785 cm² to obtain the tensile stress, which was used as a criterion for assessing magnetism. From FIG. 1, it can be seen that when a Pt content is beyond 87 atomic %, the attaching force of the Co—Pt alloy to the magnet becomes zero, making the alloy nonmagnetic. However, it is not preferable that there is a phase containing Pt as the main component since the deposition speed of Pt is faster than Co or Cr as mentioned in the Background Art section, the problem of a change of composition would occur during deposition. On the other hand, FIG. 1 shows that although the attaching force to a magnet decreases when the Pt content decreases to 50 atomic % or lower, the attaching force still exists even at a content of 10 atomic % or lower, this means that the alloy is magnetic. However, it is difficult to maintain the nonmagnetic feature of the Co—Cr—Pt phase when the amount of Pt in the Co—Cr—Pt phase is increased, as described below. Hence, it would be necessary to incorporate a certain amount of Pt in the Co—Pt phase to satisfy the desired Pt amount in the composition of the entire target. As such, the Co—Pt magnetic phase is composed to include Pt at an amount of 4 atomic % or higher and 10 atomic % or lower. As mentioned above, when the amount of Pt contained in the Co—Pt magnetic phase falls below 4 atomic %, the amount of Pt in the Co—Cr—Pt phase would become excessive, therefore it is difficult to maintain the nonmagnetic feature of the Co—Cr—Pt phase, and such situation is not desirable. Furthermore, a content of Pt in the Co—Pt magnetic phase exceeding 10 atomic % leads to a decreased Pt content in the Co—Cr—Pt phase, so that the amount of oxide content in the target relatively increases compared to the amount of Co—Cr—Pt alloy content, which causes oxides aggregation with ease when the Co—Cr—Pt powder is mixed with oxides leading to particle generation during sputtering, so such situation is not preferable.

3. Co—Cr—Pt Nonmagnetic Phase

The Co—Cr—Pt nonmagnetic phase of the present disclosure may include impurities or intentional additive elements as long as it is a nonmagnetic phase containing Co, Cr and Pt.

The Co—Cr—Pt phase comprises Co and Cr being included at proportions of 30 atomic % or more of Cr and 70 atomic % or less of Co. The proportion of Cr may be calculated by (Cr(at %)/(Co(at %)+Cr(at %))).

FIG. 2 shows the effect of the Cr content on the attaching force of an alloy of Co and Cr (hereinafter referred to as “Co—Cr alloy”) to a magnet. Other than mixing Co and Cr to a volume of 1 cm³, the same process used for obtaining data in FIG. 1 was carried out to obtain FIG. 2. It can be seen from FIG. 2 that when the proportion of Cr against Co is 25 atomic % or higher, the attaching force of the alloy to the magnet is approximately zero, and the Co—Cr alloy becomes nonmagnetic, but when the proportion of Cr is 25 atomic % or lower, the attaching force of the alloy to the magnet shoots up and the alloy turns magnetic. Hence, the proportion of Cr in the Co—Cr alloy should preferably be 25 atomic % or higher to form a nonmagnetic phase.

In addition, a rise in the Pt content in the Co—Cr—Pt nonmagnetic phase leads to a corresponding rise in the Cr content required for making the Co—Cr—Pt phase nonmagnetic. Hence, it is preferable to provide a sufficiently nonmagnetic Co—Cr—Pt phase by setting the amount of Cr against the total of Co and Cr to 30 atomic % or higher.

The amount of Pt in the Co—Cr—Pt phase is determined by the amount of Pt required in the entire target. Since the Co—Pt phase includes Pt at 10 atomic % or lower as mentioned before, the amount of Pt in the Co—Cr—Pt magnetic phase is the amount left after subtracting the amount of Pt in the Co—Pt magnetic phase from the amount of Pt in the entire target. Since the amount of Pt is determined by the demand of the whole composition, there is no particular restriction as to the upper limit or the lower limit, but an increase in the amount of Pt would necessitate an increased amount of Cr to maintain the Co—Cr—Pt phase as a nonmagnetic phase, therefore it is preferable for the amount of Pt in the Co—Cr—Pt phase to be 30 atomic % or lower.

The Co—Cr—Pt phase further includes at least one element selected from a group consisting of B, Ti, V, Mn, Zr, Nb, Ru, Mo, Ta and W. These additional elements are added mainly because they are demanded in the composition of the desired magnetic thin film.

4. Oxide Phase

The oxide phase may include an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof. These oxides are added because they are demanded in the composition of the desired magnetic thin film.

Oxides that may be incorporated include, for example, SiO₂, TiO₂, Ti₂O₃, Ta₂O₅, Cr₂O₃, CoO, Co₃O₄, B₂O₃, Fe₂O₃, CuO, Y₂O₃, MgO, Al₂O₃, ZrO₂, Nb₂O₅, MoO₃, CeO₂, Sm₂O₃, Gd₂O₃, WO₂, WO₃, HfO₂, NiO₂.

The oxide phase is basically nonmagnetic, and it is unlikely to have a negative effect on the pass-through-flux (PTF), so the amount to be added is regulated according to the composition of the desired magnetic thin film.

5. Fine Structure

FIG. 3 illustrates a metallurgical microscope photograph of the sputtering target prepared in Example 1, below. It is a photograph of a cross section cut in the direction of the thickness of a target specimen.

As shown in FIG. 3, the Co—Pt magnetic phase has a cross section with a circular or elliptic shape in which an aspect ratio of a major axis and a minor axis is in a range of 1 to 2.5 or a polygonal shape in which an aspect ratio of a longest distance between opposing vertexes and a shortest distance between opposing vertexes is in a range of 1 to 2.5, when the sputtering target of the present invention is observed by a metallurgical microscope. It is desirable for the shape of the Co—Pt phase to be close to a sphere as possible to prevent the spread of alloy elements and maintain the desired composition, and the aspect ratio of the major axis and the minor axis may preferably be in the range of 1 to 1.5. Further, the Co—Cr—Pt nonmagnetic phase has a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher when observed by an electron microscope. In other words, a flat circle, an ellipse or polygons such as a rectangle in FIG. 3 are Co—Cr—Pt nonmagnetic phases. The Co—Cr—Pt phase should preferably be fully mixed with oxides and have a structure in which oxides are finely dispersed in the base, therefore a shape that is compressed as flatly as possible and segmented by oxide particles is preferable, and the aspect ratio of a major axis and a minor axis may preferably be 4 or higher and more preferably 5 or higher.

The Co—Pt phase is derived from an atomized powder created by atomization, and the average diameter estimated from the metallurgical microscope photograph is about 40 μm to 60 μm. Further, the Co—Cr—Pt phase is also derived from an atomized powder created by atomization, but it breaks or transforms to a flat shape when it is mixed with an oxide powder and subjected to mechanical treatment. The average major axis is 20 μm to 30 μm, and the average minor axis is 2 μm to 10 μm. Note that the Co—Pt phase is spherical in the photograph, but the Co—Pt phase may be formed using the mechanically treated, atomized powder, as mentioned hereinafter, and in those cases, the phase will have an oblate, rectangular or polygonal shape.

6. Manufacture Process

The manufacture process of the sputtering target is shown below.

### (1) Preparation of Co—Pt Powder

Co and Pt are measured off to a predetermined composition whose proportion of Pt is 4 to 10 atomic %. Then, the mixture is melted to prepare molten metal of alloy, and powderized by gas atomization. A generally known method may be used for gas atomization. The Co—Pt powder that has been formed is a spherical powder, which has a distribution of particle size whose range is from about a few μm to 200 μm, with the average particle size being 40 μm to 60 μm. The powder is appropriately classified by a sieve to remove fine powder and coarse powder to obtain a unified particle size. The range of the particle size after sifting the powder is preferably 10 μm to 100 μm, and more preferably 40 μm to 100 μm. In addition, the average particle size after sifting is about 40 μm to 60 μm similar to that before sifting. The fine powder has a large specific surface, therefore the compositions of the phases tend to shift during the sintering of the target due to the atoms spreading between the Co—Pt phase and the Co—Cr—Pt phase, and thus, it is difficult to obtain the desired composition.

### (2) Preparation of Co—Cr—Pt Powder

Co, Cr and Pt are measured off to a predetermined composition, which is to include Co and Cr at proportions of 30 atomic % or more of Cr and 70 atomic % or less of Co. Then, the mixture is melted to prepare molten metal, and powderized by gas atomization. The Co—Cr—Pt powder that has been formed is a spherical powder, having a particle size distribution of about a few μm to 200 μm, with the average particle size being 40 μm to 60 μm. The powder is appropriately classified by a sieve to remove fine powder and coarse powder to obtain a unified particle size. The range of the particle size after sifting the powder is preferably 10 μm to 100 μm. In addition, the average particle size after sifting is about 40 μm to 60 μm similar to that before sifting.

Furthermore, when one or more additional elements are added to the Co—Cr—Pt powder, desired amounts of additional elements are also measured off in the measuring step to be gas atomized to form a powder including the additional elements.

### (3) Mixture of the Co—Cr—Pt Powder and the Oxide Powder

The Co—Cr—Pt powder formed by gas atomization and an oxide powder having a particle size of 0.1 μm to 10 μm are mixed to obtain the first powder mixture. Any method of treatment, such as the ball mill, may be used for mixing. Mixing is preferably continued until the Co—Cr—Pt powder is broken or until it is deformed from a spherical shape to a flat shape. To prevent failures, such as arcing, during sputtering, it is desirable to mix the Co—Cr—Pt powder and the oxide powder to a sufficient uniformity, until the secondary particle size of the oxide powder reaches the predetermined range.

### (4) Mechanical Treatment of the Co—Pt Powder

The powder formed by atomization may contain voids called blow halls. The voids act as a point of plasma concentration during sputtering, which causes the risk of instabilizing discharged voltage. It is thus desirable to introduce a step of collapsing the blow holes by mechanically treating the atomized powder.

The disclosed methods are expected to allow collapsing of blow holes during the mixing treatment of the Co—Cr—Pt powder and the oxide powder. On the other hand, the Co—Pt magnetic powder does not mix with an oxide powder, so it is preferable to collapse blow holes by processing only the Co—Pt magnetic powder in the ball mill. When such mechanic processing is performed, the Co—Pt magnetic powder may take not just a spherical shape, but also an oblate shape, a rectangular shape or a polymorphic shape.

### (5) Mixing Treatment of Co—Cr—Pt/Oxide Powder Mixture and Co—Pt Powder

The first powder mixture of Co—Cr—Pt powder and oxides are further mixed with the Co—Pt powder to obtain the second powder mixture. The mixing treatment may be performed by any methods, such as the Turbula shaker, or the ball mill.

By performing the mixing treatment only to the extent that the first powder mixture (Co—Cr—Pt and an oxide) and the Co—Pt powder are both deformed, but their particle sizes are not too small, the spreading of metal between the powders would be regulated even during hot press, and a shift of the alloy elements in each of the powders during hot press may be prevented. This would consequently prevent the Co—Cr—Pt phase from becoming magnetic due to the spread of the Co element from the Co—Pt powder to the Co—Cr—Pt powder, or an increase in the magnetic force of the Co—Pt phase, and this would thus contribute to an increase of the value of the pass-through-flux (PTF).

### (6) Sintering of Powder Mixture

By performing hot press of the second powder mixture of Co—Cr—Pt, an oxide and Co—Pt prepared above under any previously known condition, a sputtering target in a sintered form is obtained.

### EXAMPLES

In the following Examples, metallurgical microscope photographs taken by OLYMPUS, GX51 were used for observations.

### Example 1

The composition of the entire target prepared as Example 1 was 90 (71 Co-10 Cr-14 Pt-5 Ru)-7 SiO₂-3 Cr₂O₃. The compositional ratios of elements below all take the unit of atomic %.

The metals were measured off so that the alloy composition amounts to 46.829 Co-20.072 Cr-23.063 Pt-10.036 Ru (the proportion of Co and Cr are 70 atomic % of Co and 30 atomic % of Cr), and the alloy was heated to 1550° C. to melt the metals and form molten metal, to prepare a Co—Cr—Pt—Ru powder by gas atomization at a spraying temperature of 1750° C.

Then, the metals were measured off to form an alloy composition of 95 Co-5 Pt, the alloy was heated to 1500° C. to melt the metals and form molten metal to prepare a Co—Pt powder by gas atomization at a spraying temperature of 1700° C.

The two types of atomized powders prepared above were classified by sieves to obtain a Co—Cr—Pt—Ru powder of a particle size of 10 μm to 100 μm and a Co—Pt powder of a particle size of 10 μm to 100 μm.

To the obtained Co—Cr—Pt—Ru powder of 1065.37 g were added 107.25 g of SiO₂ powder with a particle size of 0.1 μm to 10 μm and 116.29 g of Cr₂O₃ powder with a particle size of 1 μm to 10 μm, and the mixture was mechanically treated in a ball mill to obtain the first powder mixture.

In order to crush the blow holes in the obtained Co—Pt powder, 1500 g of the Co—Pt powder was put in a ball mill by itself to be mechanically treated.

The first powder mixture (598.44 g) and the Co—Pt powder (351.56 g) were mixed at 67 rpm for 30 min. using the Turbula shaker to obtain the second powder mixture.

The second powder mixture was subjected to hot press at a sintering temperature of 1220° C., a pressure of 31 MPa, for 10 min. under a vacuum atmosphere to obtain a small sintered object (diameter 30 mm, thickness 5 mm).

The density of the obtained small sintered object was measured by the Archimedean method to be 8.555 g/cm³, which amounts to a relative density of 97.773%. Note that the relative density is a value obtained by dividing the actually measured density of the target by the theoretical density.

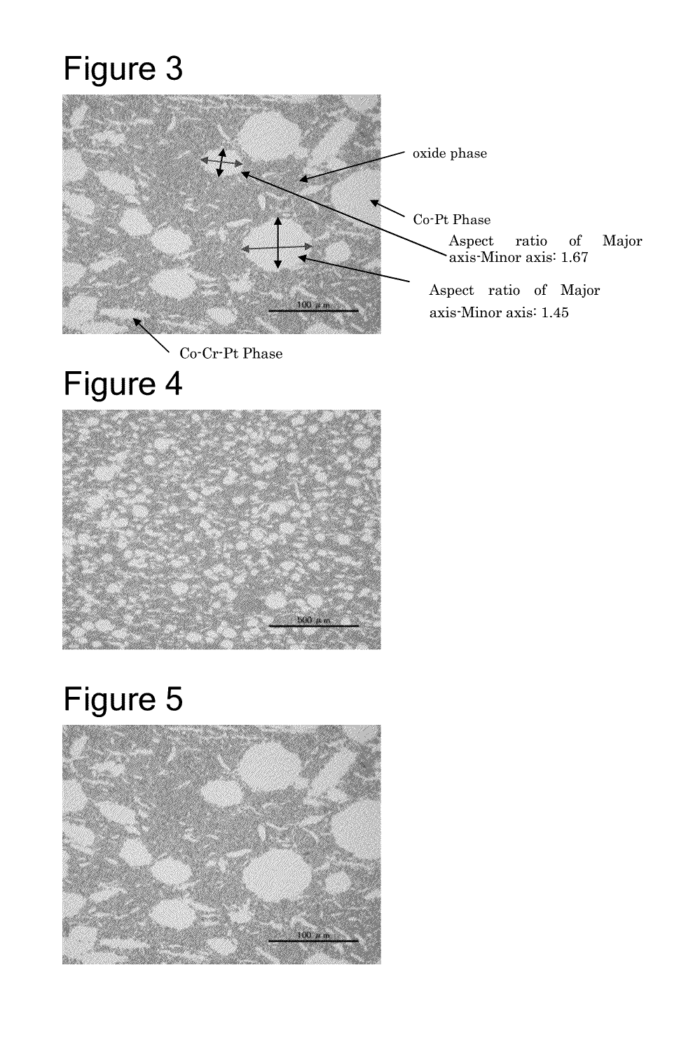

FIG. 4 and FIG. 5 show the metallurgical microscope photographs of the cross section in the thickness direction of the obtained small sintered object. FIG. 4 is a photograph at a low magnification, and FIG. 5 is a photograph at a high magnification.

In FIG. 4 and FIG. 5, the white spherical sections are the Co—Pt phases, and the similarly white, but stick-like or flat-shaped sections are the Co—Cr—Pt phases. Also, the base gray section is the oxide phase. The oxide phase is mainly formed of a SiO₂ powder, a Cr₂O₃ powder and a part of the broken Co—Cr—Pt—Ru powder and the oxide is finely dispersed in an alloy. As clear from FIG. 5, the Co—Pt phase has an almost spherical structure, and it can be seen that the shape formed by atomization is maintained as-is. The aspect ratio of the major axis and the minor axis is within 1 to 2.5. On the other hand, the Co—Cr—Pt phase is deformed into an elongated shape, and takes on a flat, stick-like or branched shape. The aspect ratio of the major axis and the minor axis (the long side and the short side) is 2.5 or higher.

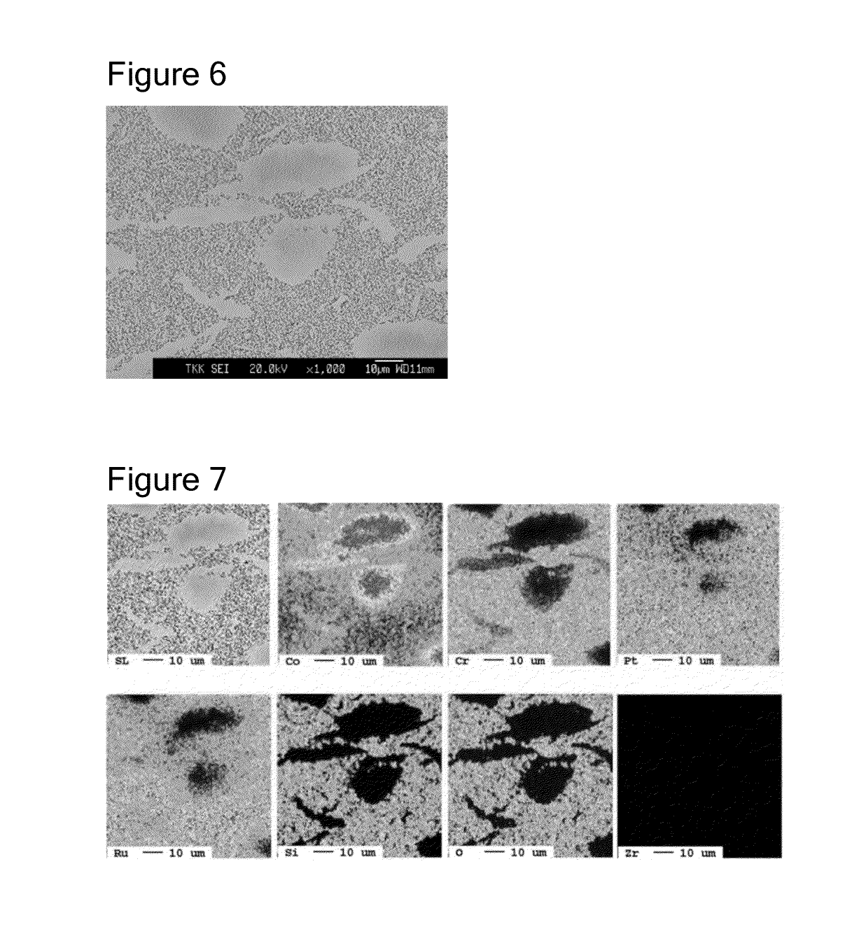

Furthermore, FIG. 6 and FIG. 7 show the results of an analysis using an electron probe microanalyzer (EPMA) for the obtained small sintered object. FIG. 6 is a scanning electron microscope (SEM) image of a sintered object, and it can be seen that spherical phases and stick-like or flat-shaped phases are dispersed in the base as in FIGS. 3 to 5. Next, in FIG. 7, the element contents of each phase is divided by color for the same portion as FIG. 6. Focusing especially on the Pt content, the spherical phase includes almost no Pt, but the stick-like phase includes more Pt than the base, and it can be seen that the spherical phase is a Co—Pt phase containing 5 atomic % of Pt, and the stick-like phase is a Co—Cr—Pt phase containing about 23 atomic % of Pt. Focusing on the other hand on the Cr content, there is of course no Cr in the Co—Pt phase, but the Co—Cr—Pt phase contains 20 atomic % of Cr, and the oxide phase in which Cr₂O₃ is mixed into the Co—Cr—Pt powder as an oxide contains more than 20 atomic % of Cr.

Next, the same second powder mixture is used to perform hot press at the same condition as creating a small sintered object and to obtain a large sintered object (diameter 152.4 mm, thickness 5.00 mm). The density of the obtained large sintered object was calculated to be 8.686 g/cm³, which amounts to a relative density of 99.272%.

The obtained large sintered object was assessed by a pass-through-flux (PTF) according to ASTM F2086-01. As the magnet for generating magnetic flux, a horseshoe magnet (material:alnico) was used. The magnet was attached to the PTF measurement device and also a gauss meter (produced by FW-BELL, serial number: 5170) was connected to a hall probe. The hall probe (produce by FW-BELL, serial number: STH17-0404) was arranged right above the center of the magnetic poles of the horse shoe magnet.

Firstly, the Source Field (SOF) was measured by the magnetic flux density in a horizontal direction to the table surface without placing the target on the table of the measurement device, and the result was 892 (G).

Secondly, the end of the hall probe was raised to the measuring position of leakage of the magnetic flux of the target (position at a height of the thickness of the target+2 mm from the table surface), and the Reference field (REF) was measured by measuring the magnetic flux density in a horizontal direction to the table surface without placing the target on the table of the measurement device, and the result was 607 (G).

Thirdly, the target was placed on the table surface so that the distance between the center of the target surface and the point right below the hall probe on the target surface was 43.7 mm. Then, the target was rotated counterclockwise 5 times without moving the center position, followed by rotating the target to 0 degree, 30 degrees, 60 degrees, 90 degrees and 120 degrees without moving the center position, to measure the magnetic flux density (the leakage magnetic flux density) in a horizontal direction of the table surface. The obtained five values of the leakage magnetic flux density divided by the value of REF and multiplied by 100 was determined as PTF (%). The average of the five PTF (%) was taken as the average PTF (%) of the target. As shown in Table 1 below, the average PTF (%) was 62.1%.

TABLE 1
ASTM

| | | PTF [G/%] | | | | | |
|---|---|---|---|---|---|---|---|
| SOF | REF | 1st | 2nd | 3rd | 4th | 5th | Ave. |
| 892 | 607 | 377 | 377 | 377 | 377 | 377 | |
| | | 62.1 | 62.1 | 62.1 | 62.1 | 62.1 | 62.1 |

### Comparative Example 1

The composition of the entire target prepared as Comparative Example 1 is the same as Example 1, which is 90 (71 Co-10 Cr-14 Pt-5 Ru)-7 SiO₂-3 Cr₂O₃.

The metals were measured off so that the alloy composition amounts to 71 Co-10 Cr-14 Pt-5 Ru, and the alloy was heated to 1550° C. to melt the metals and form molten metal to prepare an atomized powder by gas atomization at a spraying temperature of 1750° C.

The atomized powder was classified by a sieve to obtain a Co—Cr—Pt—Ru powder of a particle size of 10 μm to 100 μm.

To the obtained Co—Cr—Pt—Ru powder (900.00 g) was added 52.96 g of SiO₂ powder with a particle size of 0.1 μm-10 μm and 57.42 g of Cr₂O₃ powder with a particle size of 1 μm-10 μm, and the mixture was mechanically treated in a ball mill to obtain the first powder mixture.

The second powder mixture was subjected to hot press at a sintering temperature of 1130° C., a pressure of 31 MPa, for 10 min. under a vacuum atmosphere to obtain a small sintered object (diameter 30 mm, thickness 5 mm).

The density of the obtained small sintered object was measured by the Archimedean method to be 8.567 g/cm³, which amounts to a relative density of 97.940%.

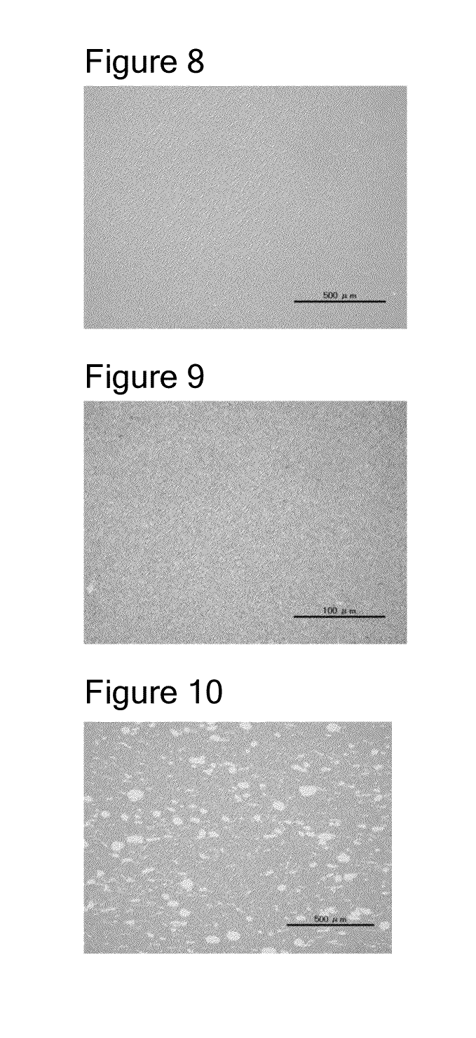

FIG. 8 and FIG. 9 show the metallurgical microscope photographs of the cross section in the thickness direction of the obtained small sintered object. FIG. 8 is a photograph at a low magnification, and FIG. 9 is a photograph at a high magnification.

As seen from FIG. 8 and FIG. 9, Comparative Example 1 does not use a Co—Pt powder, and the Co—Cr—Pt—Ru powder and two types of oxide powders are mixed uniformly by mechanical treatment, so that the fine structure is composed of a single phase containing oxides.

Next, the same powder mixture was used to perform hot press at the same condition as creating a small sintered object and to obtain a large sintered object (diameter 152.4 mm, thickness 5.00 mm). The density of the obtained large sintered object was calculated to be 8.654 g/cm³, which amounts to a relative density of 98.900%.

The obtained large sintered object was assessed by a pass-through-flux (PTF) according to ASTM F2086-01, and the result was PTF of 51.2%.

### Comparative Example 2

The composition of the entire target formed by Comparative Example 2 was 90 (71 Co-10 Cr-14 Pt-5 Ru)-7 SiO₂-3 Cr₂O₃, the same as Example 1.

The metals were measured off so that the alloy composition amounts to 66.733 Co-11.776 Cr-15.603 Pt-5.888 Ru (Cr/(Co+Cr) is 15 atomic %), and the alloy was heated to 1550° C. to melt the metals and form molten metal to prepare a Co—Cr—Pt—Ru powder by gas atomization at a spraying temperature of 1750° C.

Next, the metals were measured off to an alloy composition of 95 Co-5 Pt to prepare the Co—Pt powder similarly to Example 1.

The two types of atomized powders prepared above were classified by sieves to obtain a Co—Cr—Pt—Ru powder of a particle size of 10 μm to 100 μm and a Co—Pt powder of a particle size of 10 μm to 100 μm.

To the obtained Co—Cr—Pt—Ru powder of 824.10 g was added 55.41 g of a SiO₂ powder with a particle size of 0.1 to 10 μm and 60.08 g of a Cr₂O₃ powder with a particle size of 1 μm to 10 μm, and the mixture was mechanically treated in a ball mill to obtain the first powder mixture.

Furthermore, mechanical treatment was performed against the obtained Co—Pt powder similarly to Example 1.

The first powder mixture (844.41 g) and the Co—Pt powder (105.59 g) were mixed at 67 rpm for 30 min. using the Turbula shaker to obtain the second powder mixture.

The second powder mixture was subjected to hot press at a sintering temperature of 1170° C., a pressure of 31 MPa for 10 min. under a vacuum atmosphere to obtain a small sintered object (diameter 30 mm, thickness 5 mm).

The density of the obtained small sintered object was measured by the Archimedean method to be 8.651 g/cm³, which amounts to a relative density of 98.867%.

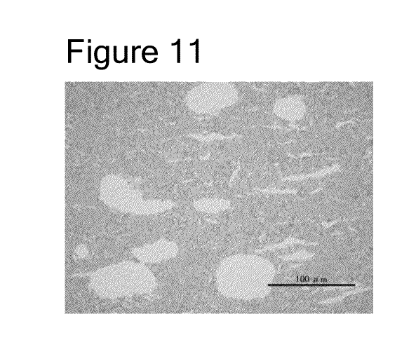

FIG. 10 and FIG. 11 show the metallurgical microscope photographs of the cross section in the thickness direction of the obtained small sintered object. FIG. 10 is a photograph at a low magnification, and FIG. 11 is a photograph at a high magnification. The shape of the tissue is almost the same as Example 1, and the white spherical sections are the Co—Pt phases, and the similarly white, but stick-like or flat-shaped sections are the Co—Cr—Pt phases. Also, the base gray section is the oxide phase.

Next, the same second powder mixture was used to perform hot press at the same condition as creating a small sintered object and to obtain a large sintered object (diameter 152.4 mm, thickness 5.00 mm). The density of the obtained large sintered object was calculated to be 8.673 g/cm³, which amounts to a relative density of 99.122%.

The obtained large sintered object was assessed by a pass-through-flux (PTF) similarly to Example 1, and the result is shown in Table 2.

TABLE 2
ASTM

| | | PTF [G/%] | | | | | |
|---|---|---|---|---|---|---|---|
| SOF | REF | 1st | 2nd | 3rd | 4th | 5th | Ave. |
| 891 | 604 | 343 | 343 | 343 | 344 | 344 | |
| | | 56.8 | 56.8 | 56.8 | 57.0 | 57.0 | 56.9 |

In Example 1 of the present invention, the amount of Pt contained in the Co—Pt phase is small at 10 atomic % or lower, and Co and Cr are included in the Co—Cr—Pt phase at proportions of 30 atomic % or more of Cr and 70 atomic % or less of Co, therefore the pass-through-flux (PTF) may be far higher even though the composition is the same as the Comparative Example.

When Example 1 and Comparative Example 1 are compared, the proportion of Co and Cr in Comparative Example 1 is shown as about 12 atomic % of Cr (Co: 71 atomic %, Cr: 10 atomic %), since the target as a whole is a uniform composition. Hence, it is not possible to make the entire target nonmagnetic, and the pass-through-flux (PTF) is not able to be increased. In comparison, in Example 1, the proportion of Co and Cr in the Co—Cr—Pt phase in the target may be 30 atomic % of Cr and 70 atomic % of Co, so the phase may be a nonmagnetic phase, and the pass-through-flux (PTF) may increase.

Further, when Example 1 and Comparative Example 2 are compared, they are both characterized by a fine structure of a three-phase structure, but Comparative Example 2 differs from Example 1 in that the ratio of Co and Cr included in the Co—Cr—Pt phase is such that the ratio of Cr is low at about 15%, which is 30 atomic % or lower, so the Co—Cr—Pt phase is not nonmagnetic. Hence, the magnetic flux is introduced in the Co—Cr—Pt phase, and the pass-through-flux (PTF) is reduced. On the other hand, the Co—Cr—Pt phase in Example 1 is a nonmagnetic phase, so a high pass-through-flux (PTF) can be achieved.

### Example 2

The rate of Pt in the Co—Pt phase was altered in the range of 4 atomic % to 10 atomic %, and (2) the rate of Cr (Cr/(Cr+Co)) in the Co—Cr—Pt phase was altered in the range of 30 atomic % to 95 atomic % of Cr, and SiO₂, TiO₂ and Co₃O₄ were used as oxides to manufacture the sintered object (Co—Cr—Pt—Ru—SiO₂—TiO₂—Co₃O₄) by a similar process as Example 1 to assess the pass-through-flux (PTF). The content ratio (volume %) of the materials of each sintered object and the pass-through-flux (PTF) are shown in Table 3.

TABLE 3

| | First Powder Mixture | | | | | | | | | Co—Pt | First Powder | Co—Pt | |
|---|---|---|---|---|---|---|---|---|---|---|---|---|---|
| | | Co—Cr—Pt phase (vol %) | | | | Oxide phase (vol %) | | | | phase | Mixture | Mixture | |
| No. | Or/(Oo + Or) | Co | Cr | Pt | Ru | SiO2 | TiO2 | Co3O4 | SUM | Pt (at %) | (vol %) | (vol %) | PTF (%) |
| 1 | 30 | 28.11% | 13.10% | 15.50% | 7.40% | 11.05% | 8.04% | 16.81% | 100.00% | 4 | 77.55% | 22.45% | 59.6 |
| 2 | 30 | 28.23% | 13.15% | 15.15% | 7.43% | 11.09% | 8.07% | 16.88% | 100.00% | 5 | 76.98% | 23.02% | 60.1 |
| 3 | 30 | 28.35% | 13.21% | 14.79% | 7.46% | 11.14% | 8.10% | 16.95% | 100.00% | 6 | 76.40% | 23.60% | 60.6 |
| 4 | 30 | 28.47% | 13.27% | 14.42% | 7.49% | 11.19% | 8.14% | 17.02% | 100.00% | 7 | 75.80% | 24.20% | 61.0 |
| 5 | 30 | 28.60% | 13.32% | 14.04% | 7.53% | 11.24% | 8.18% | 17.10% | 100.00% | 8 | 75.19% | 24.81% | 61.5 |
| 6 | 30 | 28.73% | 13.39% | 13.65% | 7.56% | 11.29% | 8.21% | 17.18% | 100.00% | 9 | 74.56% | 25.44% | 62.1 |
| 7 | 30 | 28.86% | 13.45% | 13.24% | 7.60% | 11.34% | 8.25% | 17.26% | 100.00% | 10 | 73.92% | 26.08% | 62.6 |
| 8 | 35 | 23.82% | 13.94% | 16.15% | 7.88% | 11.76% | 8.56% | 17.89% | 100.00% | 4 | 72.84% | 27.16% | 56.5 |
| 9 | 35 | 24.64% | 14.43% | 13.25% | 8.15% | 12.17% | 8.85% | 18.51% | 100.00% | 10 | 68.38% | 31.62% | 60.2 |
| 10 | 40 | 20.22% | 14.65% | 16.70% | 8.28% | 12.36% | 8.99% | 18.80% | 100.00% | 4 | 69.32% | 30.68% | 53.8 |
| 11 | 40 | 21.05% | 15.26% | 13.25% | 8.62% | 12.87% | 9.36% | 19.58% | 100.00% | 10 | 64.20% | 35.80% | 58.2 |
| 12 | 45 | 17.15% | 15.26% | 17.17% | 8.62% | 12.87% | 9.36% | 19.58% | 100.00% | 4 | 66.57% | 33.43% | 52.1 |
| 13 | 45 | 17.96% | 15.98% | 13.25% | 9.03% | 13.47% | 9.80% | 20.50% | 100.00% | 10 | 60.92% | 39.08% | 56.3 |
| 14 | 50 | 14.51% | 15.78% | 17.57% | 8.91% | 13.30% | 9.68% | 20.25% | 100.00% | 4 | 64.38% | 35.62% | 51.3 |
| 15 | 50 | 15.27% | 16.60% | 13.26% | 9.38% | 14.00% | 10.19% | 21.31% | 100.00% | 10 | 58.27% | 41.73% | 54.4 |
| 16 | 55 | 12.21% | 16.23% | 17.92% | 9.17% | 13.69% | 9.96% | 20.83% | 100.00% | 4 | 62.58% | 37.42% | 50.6 |
| 17 | 55 | 12.91% | 17.15% | 13.26% | 9.69% | 14.46% | 10.52% | 22.01% | 100.00% | 10 | 56.10% | 43.90% | 53.8 |
| 18 | 60 | 10.20% | 16.63% | 18.22% | 9.39% | 14.02% | 10.20% | 21.34% | 100.00% | 4 | 61.09% | 38.91% | 49.9 |
| 19 | 60 | 10.81% | 17.64% | 13.26% | 9.96% | 14.87% | 10.82% | 22.63% | 100.00% | 10 | 54.27% | 45.73% | 53.3 |
| 20 | 65 | 8.41% | 16.98% | 18.50% | 9.59% | 14.32% | 10.42% | 21.79% | 100.00% | 4 | 59.82% | 40.18% | 49.4 |
| 21 | 65 | 8.95% | 18.07% | 13.26% | 10.21% | 15.24% | 11.09% | 23.19% | 100.00% | 10 | 52.71% | 47.29% | 52.8 |
| 22 | 70 | 6.82% | 17.29% | 18.74% | 9.77% | 14.58% | 10.61% | 22.19% | 100.00% | 4 | 58.74% | 41.26% | 48.8 |
| 23 | 70 | 7.28% | 18.46% | 13.26% | 10.43% | 15.56% | 11.33% | 23.69% | 100.00% | 10 | 51.37% | 48.63% | 52.4 |
| 24 | 75 | 5.39% | 17.57% | 18.95% | 9.93% | 14.82% | 10.78% | 22.55% | 100.00% | 4 | 57.80% | 42.20% | 48.3 |
| 25 | 75 | 5.77% | 18.81% | 13.27% | 10.62% | 15.86% | 11.54% | 24.14% | 100.00% | 10 | 50.20% | 49.80% | 52.0 |
| 26 | 80 | 4.10% | 17.83% | 19.15% | 10.07% | 15.03% | 10.94% | 22.88% | 100.00% | 4 | 56.97% | 43.03% | 51.4 |
| 27 | 80 | 4.40% | 19.13% | 13.27% | 10.80% | 16.13% | 11.74% | 24.54% | 100.00% | 10 | 49.17% | 50.83% | 54.1 |
| 28 | 85 | 2.93% | 18.06% | 19.33% | 10.20% | 15.23% | 11.08% | 23.17% | 100.00% | 4 | 56.25% | 43.75% | 51.5 |
| 29 | 85 | 3.15% | 19.41% | 13.27% | 10.97% | 16.37% | 11.91% | 24.91% | 100.00% | 10 | 48.25% | 51.75% | 54.3 |
| 30 | 90 | 1.87% | 18.27% | 19.49% | 10.32% | 15.40% | 11.21% | 23.44% | 100.00% | 4 | 55.60% | 44.40% | 51.5 |
| 31 | 90 | 2.01% | 19.68% | 13.27% | 11.12% | 16.59% | 12.08% | 25.25% | 100.00% | 10 | 47.44% | 52.56% | 54.4 |
| 32 | 95 | 0.89% | 18.46% | 19.64% | 10.43% | 15.57% | 11.33% | 23.69% | 100.00% | 4 | 55.03% | 44.97% | 51.6 |
| 33 | 95 | 0.96% | 19.92% | 13.27% | 11.25% | 16.80% | 12.22% | 25.57% | 100.00% | 10 | 46.70% | 53.30% | 54.6 |

1. A target for magnetron sputtering consisting essentially of a three-phase structure, the three-phase structure comprising:
(1) a Co—Pt magnetic phase including Co and Pt, wherein Pt is included at a proportion of 4 atomic % to 10 atomic %;
(2) a Co—Cr—Pt nonmagnetic phase including Co, Cr and Pt, wherein Co and Cr are included at proportions of 30 atomic % or more of Cr and 70 atomic % or less of Co; and
(3) an oxide phase including finely dispersed metal oxides.

2. The target for magnetron sputtering according to claim 1, wherein the Co—Cr—Pt nonmagnetic phase further includes at least one element selected from a group consisting of B, Ti, V, Mn, Zr, Nb, Ru, Mo, Ta and W.

3. The target for magnetron sputtering according to claim 1, wherein the oxide phase includes an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof.

4. The target for magnetron sputtering according to claim 1, wherein the Co—Pt magnetic phase has a cross section with a circular or elliptic shape in which an aspect ratio of a major axis and a minor axis is in a range of 1 to 2.5 or a polygonal shape in which an aspect ratio of a longest distance between opposing vertexes and a shortest distance between opposing vertexes is in a range of 1 to 2.5, when observed by an electron microscope.

5. The target for magnetron sputtering according to claim 1, wherein the Co—Cr—Pt nonmagnetic phase has a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher, when observed by an electron microscope.

6. A manufacture process of a target for magnetron sputtering comprising:
a first mixing step for formulating a first powder mixture by mixing an oxide and a nonmagnetic metal powder comprising Co, Cr and Pt, wherein Co and Cr are included at proportions of 30 atomic % or more of Cr and 70 atomic % or less of Co;
a second mixing step for formulating a second powder mixture by mixing the first powder mixture, and a magnetic metal powder comprising Co and Pt, wherein Pt is included at a proportion of 4 atomic % to 10 atomic %; and
a step of sintering the second powder mixture.

7. The process according to claim 6, wherein the nonmagnetic metal powder further includes at least one element selected from a group consisting of B, Ti, V, Mn, Zr, Nb, Ru, Mo, Ta, W.

8. The process according to claim 6, wherein the oxide powder comprises an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof.

9. The process according to claim 6, wherein the nonmagnetic metal powder and/or the magnetic metal powder is formulated as an alloy.

10. The process according to claim 9, wherein the nonmagnetic metal powder and the magnetic metal powder are alloy powders formulated by an atomization method.

11. The process according to claim 6 further comprising a step of collapsing a blow hole by applying a mechanical treatment on the magnetic metal powder before the second mixing step.

12. The target for magnetron sputtering according to claim 2, wherein (3) the oxide phase includes an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof.

13. The target for magnetron sputtering according to claim 2, wherein the Co—Pt magnetic phase has a cross section with a circular or elliptic shape in which an aspect ratio of a major axis and a minor axis is in a range of 1 to 2.5 or a polygonal shape in which an aspect ratio of a longest distance between opposing vertexes and a shortest distance between opposing vertexes is in a range of 1 to 2.5, when observed by an electron microscope.

14. The target for magnetron sputtering according to claim 3, wherein the Co—Pt magnetic phase has a cross section with a circular or elliptic shape in which an aspect ratio of a major axis and a minor axis is in a range of 1 to 2.5 or a polygonal shape in which an aspect ratio of a longest distance between opposing vertexes and a shortest distance between opposing vertexes is in a range of 1 to 2.5, when observed by an electron microscope.

15. The target for magnetron sputtering according to claim 2, wherein the Co—Cr—Pt nonmagnetic phase has a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher, when observed by an electron microscope.

16. The target for magnetron sputtering according to claim 3, wherein the Co—Cr—Pt nonmagnetic phase has a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher, when observed by an electron microscope.

17. The target for magnetron sputtering according to claim 4, wherein the Co—Cr—Pt nonmagnetic phase has a cross section with a circular or elliptic shape in which an aspect ratio of a major axis and a minor axis is 2.5 or higher or a polygonal shape in which an aspect ratio of a longest distance between opposing vertexes and a shortest distance between opposing vertexes is 2.5 or higher, when observed by an electron microscope.

18. The process according to claim 7, wherein the oxide powder comprises an oxide of at least one element selected from the group consisting of Si, Ti, Ta, Cr, Co, B, Fe, Cu, Y, Mg, Al, Zr, Nb, Mo, Ce, Sm, Gd, W, Hf, Ni or a composite oxide thereof.

19. The process according to claim 7, wherein the nonmagnetic metal powder and/or the magnetic metal powder is formulated as an alloy.

20. The process according to claim 8, wherein the nonmagnetic metal powder and/or the magnetic metal powder is formulated as an alloy.
